(19) United States
(12) Patent Application Publication
(10) Pub. No.: US 2013/0241588 A1
(43) Pub. Date: Sep. 19, 2013

(54) WAFER INSPECTION APPARATUS

(71) Applicant: TOKYO ELECTRON LIMITED, Tokyo (JP)

(72) Inventor: Hiroshi Yamada, Nirasaki City (JP)

(73) Assignee: TOKYO ELECTRON LIMITED, Tokyo (JP)

(21) Appl. No.: 13/789,730

(22) Filed: Mar. 8, 2013

(30) Foreign Application Priority Data
Mar. 14, 2012 (JP) 2012-057204

(51) Int. Cl. G01R 31/26

(52) U.S. Cl. CPC G01R 31/2601
USPC 324/750.24

(57) ABSTRACT

An inspection chamber 14 of a wafer inspection apparatus includes a probe card 20 having probes 25 on a surface facing a wafer W; a pogo frame 40 contacted with a surface of the probe card 20 opposite to the surface facing the wafer W; a chuck member 23 disposed to face the probe card 20; positioning pins 61 provided on the chuck member 23. Further, a transfer device 13 includes a transfer arm 13A having recesses 62 to be fitted to the positioning pins 61. The probe card 20 loaded into the inspection chamber 14 by the transfer arm 13A is aligned with the positioning pins 61, and the wafer W loaded into the inspection chamber 14 is aligned with the positioning pins 61. Accordingly, the probe card 20 and the wafer W are located at electrical characteristic inspection positions where electrical characteristics of semiconductor devices are inspected.

### CROSS-REFERENCE TO RELATED APPLICATION

This application claims the benefit of Japanese Patent Application No. 2012-057204 filed on Mar. 14, 2012, the entire disclosures of which are incorporated herein by reference.

### FIELD OF THE INVENTION

The present disclosure relates to a wafer inspection apparatus configured to inspect electrical characteristics of semiconductor devices formed on a wafer.

### BACKGROUND OF THE INVENTION

As a wafer inspection apparatus, there is known, for example, a burn-in inspection apparatus or a probe apparatus that inspects electrical characteristics of a multiple number of semiconductor devices formed on a wafer.

FIG. 13 is a cross sectional view schematically illustrating a configuration of a conventional probe apparatus.

Referring to FIG. 13, a probe apparatus 100 includes a loader chamber 101 serving as a wafer transfer section for transferring a wafer W; and an inspection chamber 102 for inspecting therein electrical characteristics of a multiple number of semiconductor devices formed on the wafer W. This probe apparatus 100 is configured to inspect the electrical characteristics of the semiconductor devices by controlling various types of devices in the loader chamber 101 and the inspection chamber 102 under the control of a controller. The inspection chamber 102 includes a mounting table 106, a pogo frame 109, a probe card 108, and an alignment device 110. The mounting table 106 mounts thereon a wafer W loaded from the loader chamber 101 by a loading arm 103 and is configured to be movable in X, Y, Z, and θ directions. The pogo frame 109 is disposed above the mounting table 106, and the probe card 108 is supported on the pogo frame 109. The alignment device 110 is configured to perform alignment (position adjustment) between a multiple number of probes (inspection needles) of the probe card 108 and electrodes of the semiconductor devices formed on the wafer W in cooperation with the mounting table 106. After the wafer W and the probe card 108 are aligned with each other by the alignment device 110 and the mounting table 106 in cooperation, each probe of the probe card 108 is brought into contact with the electrodes of the wafer W, so that the electrical characteristics of the multiple number of semiconductor devices formed on the wafer W are inspected (see, for example, Patent Document 1).

Patent Document 1: Japanese Patent Laid-open Publication No. 2004-140241

However, the transfer device in the conventional wafer inspection apparatus is configured to load an uninspected wafer to a certain position in the inspection chamber and unload an inspected wafer from the inspection chamber. The transfer device cannot load or unload a member other than the wafer, e.g., the probe card, into/from the inspection chamber.

### BRIEF SUMMARY OF THE INVENTION

In view of the foregoing, illustrative embodiments provide a wafer inspection apparatus capable of loading and unloading both a wafer and a probe card into and from an inspection chamber by a single transfer device, and also capable of accurately aligning the wafer with the probe card to have an electrical characteristic inspection position where electrical characteristics of semiconductor devices are inspected.

In accordance with one aspect of an illustrative embodiment, there is provided a wafer inspection apparatus having an inspection chamber for inspecting electrical characteristics of semiconductor devices formed on a wafer and a transfer device for loading and unloading the wafer into and from the inspection chamber. The inspection chamber includes a probe card having a multiple number of probes on a surface of the probe card facing the wafer; a frame that is brought into in contact with a surface of the probe card opposite to the surface of the probe card facing the wafer and supports the probe card; a table-shaped chuck member disposed to face the probe card with the wafer placed therebetween; and at least one positioning pin provided on the chuck member. Further, the transfer device includes a transfer arm having at least one recess to be fitted to the at least one positioning pin. Furthermore, the probe card is loaded into the inspection chamber by the transfer arm, and after the probe card is aligned with the at least one positioning pin by fitting the at least one recess to the at least one positioning pin, the probe card is brought into contact with and supported by the frame. Moreover, the wafer is loaded into the inspection chamber by the transfer arm, and after the wafer is aligned with the at least one positioning pin by fitting the at least one recess to the at least one positioning pin, the wafer is brought into contact with the surface of the probe card facing the wafer to become an electrical characteristic inspection state in which the electrical characteristics of the semiconductor devices are inspected.

The transfer device may further include a wafer plate detachably mounted on the transfer arm. Further, the probe card may be transferred by being mounted on the transfer arm, and the wafer may be transferred by being mounted on the transfer arm via the wafer plate.

The transfer arm may have an opening formed through a central portion of the transfer arm in a thickness direction thereof.

The number of the at least one positioning pin may be at least two, and the at least two positioning pins may be provided on the chuck member to be arranged along a periphery thereof. Further, the number of the at least one recess may be at least two, and the at least two recesses may be formed on the transfer arm to be fitted to the at least two positioning pins of the chuck member, respectively.

At least two positioning recesses may be formed on the probe card along a periphery thereof, and at least two protrusions to be fitted to the at least two positioning recesses of the probe card may be provided at the transfer arm.

The probe card may be attracted to and held on the transfer arm while being transferred, and the wafer may be attracted to and held on the transfer arm via the wafer plate while being transferred.

The wafer inspection apparatus may further include a position adjusting device configured to adjust a position of the wafer with respect to the transfer arm of the transfer device. Further, the position adjusting device may include a position adjusting chamber; a base frame that is provided in the position adjusting chamber and has an opening formed through a central portion of the base frame in a thickness direction thereof; at least one positioning pin provided on a periphery of the base frame; and a sub chuck member configured to pass through the opening of the base frame. Furthermore, the sub chuck member may be configured to pass through the opening of the base frame and the opening of the transfer arm while the at least one recess of the transfer arm on which the wafer is mounted is fitted to the at least one positioning pin of the base frame. Moreover, the sub chuck member may be configured to slightly move the wafer to align the wafer with the transfer arm.

The wafer may be mounted on the transfer arm via a wafer plate detachably mounted on the transfer arm, and the sub chuck member may be configured to slightly move the wafer along with the wafer plate to align the wafer with the transfer arm.

The number of the at least one positioning pin may be at least two, and the at least two positioning pins may be provided on the base frame to be arranged along the periphery thereof.

A position of the at least one positioning pin of the base frame may correspond to a position of the at least one positioning pin of the chuck member.

In accordance with the illustrative embodiments, the probe card is loaded into the inspection chamber by the transfer arm. Then, after the probe card is aligned with the positioning pins by fitting the recesses of the transfer arm to the positioning pins of the chuck member, the probe card is brought into contact with and supported by the frame. Further, the wafer is loaded into the inspection chamber by the same transfer arm. Then, after the wafer is aligned with the positioning pins by fitting the recesses of the transfer arm to the positioning pins of the chuck member, the wafer is brought into contact with the surface of the probe card facing the wafer to become the electrical characteristic inspection state in which the electrical characteristics of the semiconductor devices are inspected. Accordingly, both the wafer and the probe card can be loaded into and unloaded from the inspection chamber by the single transfer device, and the wafer can be accurately aligned with the probe card to have the electrical characteristic inspection position where the electrical characteristics of the semiconductor devices are inspected.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a perspective view illustrating an exterior view of a wafer inspection apparatus in accordance with an illustrative embodiment;

FIG. 2 is a cross sectional view taken along a line II-II of the wafer inspection apparatus of FIG. 1;

FIG. 3 is a cross sectional view schematically illustrating a configuration of a wafer inspection interface included in an inspection chamber of FIG. 2;

FIG. 4 is a perspective view illustrating a transfer arm of FIG. 3;

FIG. 5 is a cross sectional view taken along a line V-V of the transfer arm of FIG. 4;

FIG. 6 is a perspective view illustrating a configuration in which a wafer plate is mounted on the transfer arm of FIG. 4;

FIG. 7 is a perspective view illustrating a configuration in which a probe card is mounted on the transfer arm of FIG. 4;

FIG. 8 is a cross sectional view schematically illustrating a configuration of an alignment chamber provided in an alignment section of FIG. 2;

FIG. 9 is a process diagram for inspecting electrical characteristics of semiconductor devices on a wafer by using the wafer inspection apparatus including the wafer inspection interface of FIG. 3;

FIG. 10 is a process diagram for inspecting the electrical characteristics of the semiconductor devices on the wafer by using the wafer inspection apparatus including the wafer inspection interface of FIG. 3;

FIG. 11 is a process diagram for inspecting the electrical characteristics of the semiconductor devices on the wafer by using the wafer inspection apparatus including the wafer inspection interface of FIG. 3;

FIG. 12 is a process diagram for inspecting the electrical characteristics of the semiconductor devices on the wafer by using the wafer inspection apparatus including the wafer inspection interface of FIG. 3; and

FIG. 13 is a cross sectional view schematically illustrating a configuration of a conventional probe apparatus.

### DETAILED DESCRIPTION OF THE INVENTION

Hereinafter, illustrative embodiments will be described in detail with reference to the accompanying drawings.

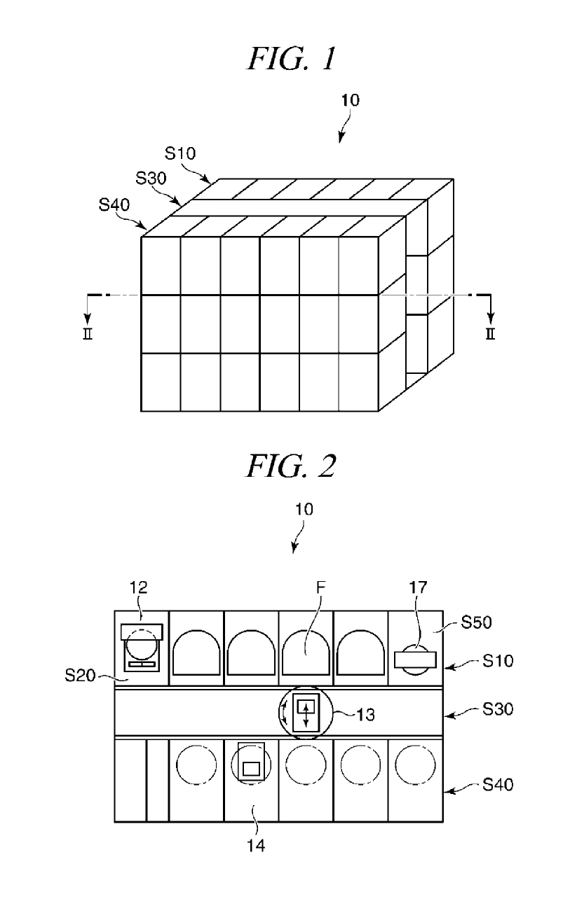

FIG. 1 is a perspective view illustrating an exterior view of a wafer inspection apparatus in accordance with an illustrative embodiment. The wafer inspection apparatus 10 is configured as a whole contact type inspection apparatus that inspects electrical characteristics by bringing all probes of a probe card into contact with all electrodes of semiconductor devices formed on a wafer at one time. This wafer inspection apparatus 10 is developed based on the technical concept of sharing many devices. Accordingly, the wafer inspection apparatus 10 includes a multiple number of inspection chambers, and the wafer is aligned by a position adjusting device provided at a place other than the inspection chambers.

In FIG. 1, the wafer inspection apparatus 10 includes a loading/unloading section S10, provided at a rear side of the wafer inspection apparatus 10, for loading and unloading a wafer; an inspection section S40 provided at a front side of the wafer inspection apparatus 10 while facing the loading/unloading section S10; and a transfer section S30 provided between the loading/unloading section S10 and the inspection section S40.

The loading/unloading section S10 is partitioned into a multiple number of unit loading/unloading areas corresponding to a multiple number of mounting devices. The inspection section S40 is also partitioned into a multiple number of unit inspection areas corresponding to a multiple number of inspection chambers. That is, each of the loading/unloading section S10 and the inspection section S40 is partitioned into the multiple number of chambers in a 3-dimensional grid shape. A transfer device to be described later (see FIG. 2) is moved in the transfer section S30 between the loading/unloading section S10 and the inspection section S40.

FIG. 2 is a cross sectional view taken along a line II-II of FIG. 1.

Referring to FIG. 2, a multiple number of accommodation devices for accommodating therein FOUPs F are provided in the loading/unloading section S10 as example mounting devices. An alignment section S20 including the position adjusting device (hereinafter, referred to as “alignment chamber”) 12 is provided at a left end of the loading/unloading section S10. A needle mark inspection section S50 including a needle mark inspection apparatus 17 is provided at a right end of the loading/unloading section S10. Further, a transfer device 13 is provided in the transfer section S30, and a multiple number of inspection chambers 14 are arranged in the inspection section S40.

The transfer device 13 includes, for example, a rotational body provided on a base; two vertically arranged transfer arms, i.e., an upper arm and a lower arm, configured to be individually moved back and forth on the rotational body in one direction; an elevation device configured to move the base and the transfer arms up and down; and a moving device configured to move these devices back and forth along the transfer section S30. For example, the wafer W is transferred while being mounted on the upper transfer arm.

In the wafer inspection apparatus 10, the transfer device 13 receives an uninspected wafer W and transfers the uninspected wafer W into the alignment chamber 12 from a FOUP F. In the alignment chamber 12, the wafer W is aligned with the transfer arm of the transfer device 13. Then, the transfer device 13 transfers the aligned wafer W into an inspection chamber 14. The inspection chamber 14 includes a wafer inspection interface 18 to be described later. The wafer inspection interface 18 is configured to inspect electrical characteristics of semiconductor devices formed on the wafer W.

Further, the transfer device 13 transfers the inspected wafer W from the inspection chamber 14 to the needle mark inspection device 17 disposed in the needle mark inspection section S50 located at one end of the loading/unloading section S10. The needle mark inspection device 17 is configured to inspect a needle mark (i.e., a mark of a contact with a probe 25) on an electrode of the respective semiconductor devices on the inspected wafer W. Then, the transfer device 13 loads the inspected wafer W into the FOUP F within the loading/unloading section S10.

Here, the transfer device 13 transfers a first wafer W unloaded from a first FOUP F into a first inspection chamber 14 via the alignment chamber 12. While inspecting the electrical characteristics of semiconductor devices formed on the first wafer W in the first inspection chamber 14, the transfer device 13 may transfer a second wafer W unloaded from a second FOUP F into a second inspection chamber 14 via the alignment chamber 12. Alternatively, while inspecting the electrical characteristics of the semiconductor devices formed on the first wafer W in the first inspection chamber 14, the transfer device 13 may unload an inspected third wafer W from a third inspection chamber and load the inspected third wafer W into a third FOUP F. That is, the transfer device 13 transfers the wafers W in sequence between the multiple number of FOUPs F and the multiple number of inspection chambers 14, and electrical characteristics of semiconductor devices formed on the wafers W are inspected in sequence in the respective inspection chambers 14.

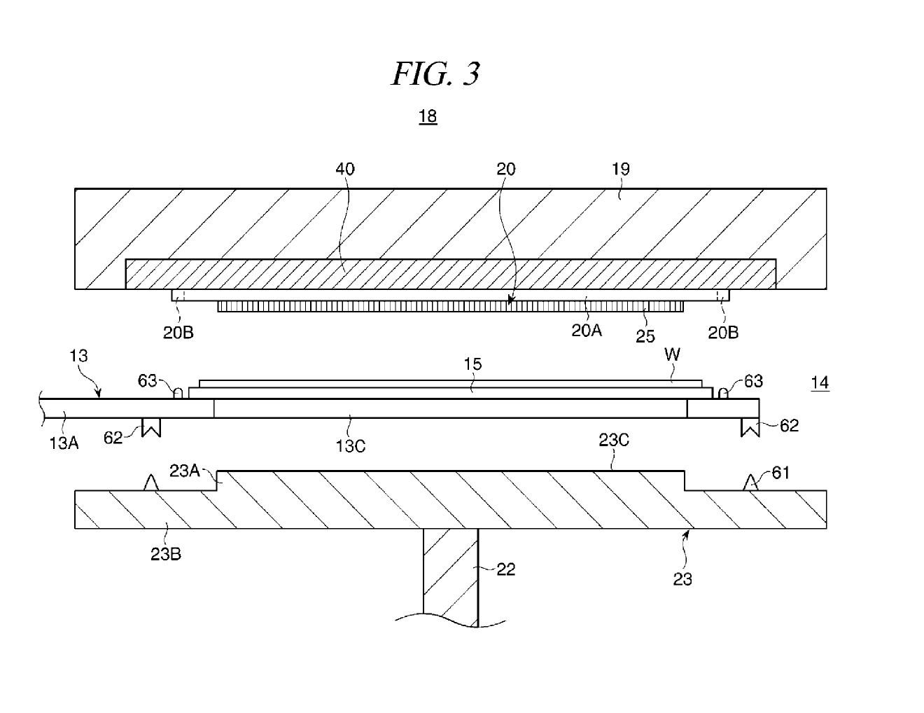

FIG. 3 is a cross sectional view schematically illustrating a configuration of a wafer inspection interface included in the inspection chamber of FIG. 2.

Referring to FIG. 3, the wafer inspection interface 18 includes a head plate 19, a frame (hereinafter, referred to as a “pogo frame”) 40, a probe card 20, a rod-shaped lifter 22 and a table-shaped chuck member 23. The head plate 19 is provided at a ceiling portion of the inspection chamber 14 and is made of a plate-shaped member. The pogo frame 40 forms a bottom surface of the head plate 19. The probe card 20 is disposed to be in contact with a bottom surface of the pogo frame 40. The lifter 22 stands uprightly from a bottom portion of the inspection chamber 14 and is configured to be moved up and down. The chuck member 23 is provided on a top portion of the lifter 22.

The probe card 20 includes a base 20A; and the probes 25 provided on a surface of the base 20A facing the wafer W. A multiple number of notches 20B are formed at the base 20A along the periphery thereof. The notches 20B are formed of, e.g., recesses, and each of the notches 20B is respectively inserted into and fitted to each of multiple positioning pins 63 provided on a transfer arm 13A of the transfer device 13 to be described later.

The chuck member 23 has a cross section in which a central portion of the chuck member 23 is protruded. Further, the chuck member 23 includes an upwardly protruding portion 23A; and a step-shaped portion 23B surrounding the protruding portion 23A and formed to be lower than the protruding portion 23A. For example, three positioning pins 61 are arranged on a top surface of the step-shaped portion 23B at a regular interval along the periphery of the step-shaped portion 23B. A top flat surface of the protruding portion 23A serves as a mounting surface 23C on which the wafer W is mounted.

The transfer device 13 includes the transfer arm 13A and a wafer plate 15 detachably mounted on the transfer arm 13A. When loading the wafer W into the inspection chamber 14, the wafer W is mounted on the transfer arm 13A via the wafer plate 15, i.e., while mounted on the wafer plate 15 and is loaded. Meanwhile, when loading the probe card 20 into the inspection chamber 14, the probe card 20 is directly mounted on the transfer arm 13A and is loaded.

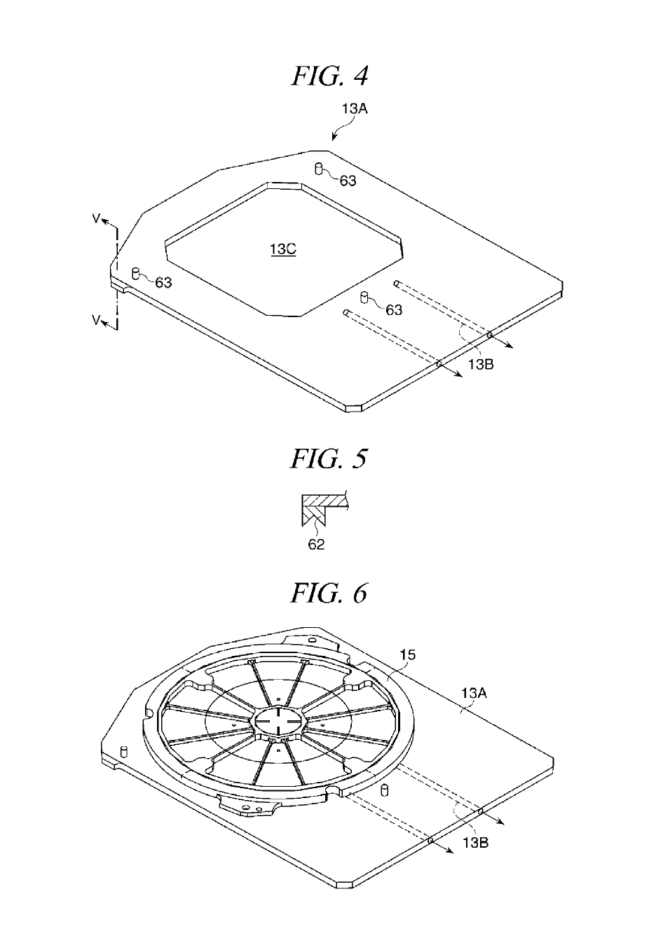

FIG. 4 is a perspective view illustrating the transfer arm 13A of FIG. 3, and FIG. 5 is a cross sectional view taken along a line V-V of the transfer arm of FIG. 4.

Referring to FIGS. 3 to 5, an opening 13C is formed through a central portion of the transfer arm 13A in a thickness direction thereof. Three insertion grooves 62 as recesses, which are arranged at a regular interval along the periphery of the transfer arm 13A, are provided on a bottom surface of a periphery of the transfer arm 13A surrounding the opening 13C. Each insertion groove 62 has a V-shaped cross sectional shape. Each of the insertion grooves 62 is fitted to each of the three positioning pins 61 on the step-shaped portion 23B of the chuck member 23. As a result, the transfer arm 13A can be aligned with the positioning pins 61, and further, the member transferred by the transfer arm 13A, e.g., the wafer W, can be aligned with the positioning pins 61. Further, three positioning pins 63 as protrusions, which are arranged at a regular interval along the periphery of the transfer arm 13A, are provided on a top surface of the transfer arm 13A. Further, an attraction line 13B for attracting and holding a member mounted on the top surface of the transfer arm 13A is formed at the transfer arm 13A. A side of the transfer arm 13A where the attraction line 13B is provided is configured as a connection part to a loader. Further, in FIG. 3, the insertion grooves 62 and the positioning pins 63 formed at the transfer arm 13A are shown to be located on the same cross section for the convenience of explanation.

FIG. 6 is a perspective view illustrating a configuration in which the wafer plate 15 is mounted on the transfer arm 13A of FIG. 4. When loading the wafer W by the transfer arm 13A having the opening 13C, the wafer plate 15 is used in order to prevent the wafer W from being bent or deformed. That is, the wafer W is mounted on the transfer arm 13A via the wafer plate 15. In an alignment chamber to be described later, the wafer W and the wafer plate 15 aligned with the transfer arm 13A are attracted and held by the attraction line 13B formed at the transfer arm 13A.

The wafer W is mounted on the wafer plate 15 aligned with the transfer arm 13A, and the wafer W is attracted via the wafer plate 15 by the attraction line 13B formed at the transfer arm 13A. Accordingly, the wafer W is indirectly held on the transfer arm 13A.

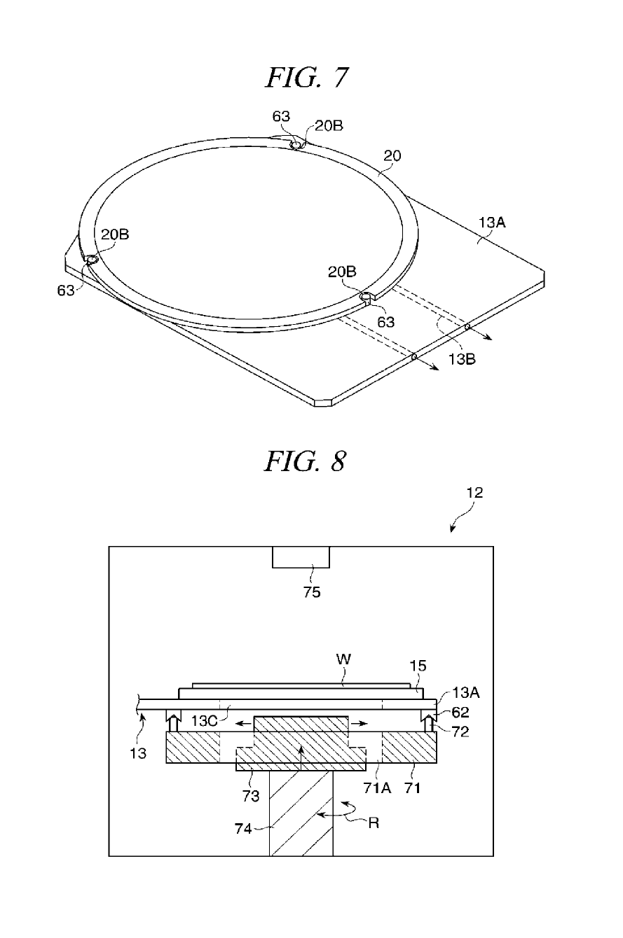

FIG. 7 is a perspective view illustrating a configuration in which the probe card 20 is mounted on the transfer arm 13A of FIG. 4.

Referring to FIGS. 3 to 7, since the probe card 20 has higher stiffness than the wafer W, the probe card 20 may not be bent even if there exists the opening 13C at the central portion of the transfer arm 13A. Accordingly, when transferring the probe card 20 by the transfer arm 13A, the probe card 20 is directly mounted on the transfer arm 13A and transferred thereon without using the wafer plate 15. The three positioning pins 63 arranged along the periphery of the transfer arm 13A at the regular interval are respectively inserted and fitted to the three notches 20B formed along the periphery of the probe card 20 at the regular interval. As a result, the probe card 20 is aligned with the transfer arm 13A. The probe card 20 aligned with the transfer arm 13A is attracted and held by the attraction line 13B formed at the transfer arm 13A.

FIG. 8 is a cross sectional view schematically illustrating an alignment chamber provided in the alignment section S20 of FIG. 2.

In FIG. 8, the alignment chamber 12 includes a base frame 71, positioning pins 72, a sub chuck member 73, and a lifter 74. The base frame 71 is positioned at a substantially central portion of the alignment chamber 12, and the base frame 71 has an opening 71A formed through a central portion thereof in a thickness direction. For example, three positioning pins 72 are provided on a top surface of the base frame 71 at a regular interval along the periphery thereof. The sub chuck member 73 is provided to pass through the opening 71A of the base frame 71. The lifter 74 serves as a position adjusting device configured to slightly move the sub chuck member 73 in X, Y, Z, and θ directions.

Positions of the positioning pins 72 provided at the base frame 71 substantially correspond to positions of the positioning pins 61 (see FIG. 3) provided at the chuck member 23 in the inspection chamber 14. Further, the probe card 20 has been aligned with the positioning pins 61 in the inspection chamber 14. Under this state, the wafer W, which has been aligned with the transfer arm 13A in the alignment chamber 12, is loaded into the inspection chamber 14 and aligned with the positioning pins 61 of the chuck member 23. As a result, the wafer W can be placed at a certain position aligned with the probe card 20. For example, the wafer can be aligned with a position in which the electrical characteristics of the semiconductor devices formed on the wafer W are inspected (hereinafter, referred to as “electrical characteristic inspection state”).

In the alignment chamber 12 having the above-described configuration, the positioning of the wafer W with respect to the transfer arm 13A is performed as follows.

That is, the transfer device 13 receives an uninspected wafer W from the FOUP F (see FIG. 2). This uninspected wafer W is mounted on the transfer arm 13A via the wafer plate 15 and is transferred into the alignment chamber 12. Then, the transfer arm 13A is placed on the base frame 71. At this time, for example, the three insertion grooves 62 formed on the bottom surface of the transfer arm 13A are inserted and fitted to, for example, the three positioning pins 72 provided at the base frame 71, respectively. As a result, the transfer arm 13A is aligned with the positioning pins 72.

At this time, the position of the wafer W is detected by a monitoring camera 75 provided at a ceiling portion of the alignment chamber 12. That is, it is checked whether the position of the wafer W with respect to the positioning pins 72 of the base frame 71, i.e., the position of the wafer W with respect to the transfer arm 13A is coincident with a previously detected certain position, i.e., an electrical characteristic inspection position where the electrical characteristics of the semiconductor devices formed on the wafer are inspected, with respect to the probe card 20 aligned with the positioning pins 61 of the chuck member 23 in the inspection chamber 14. If the position of the wafer W is found to be coincident with the electrical characteristic inspection position, the wafer W is loaded into the inspection chamber 14 by the transfer arm 13A. If, however, the position of the wafer W is not coincident with the electrical characteristic inspection position, the sub chuck member 73 is moved up by the lifter 74 to be protruded above the opening 71A of the base frame 71 and the opening 13C of the transfer arm 13A. Then, a top surface of the sub chuck member 73 is brought into contact with a bottom surface of the wafer plate 15. In this state, the sub chuck member 73 is moved up and down or in left and right directions, or rotated in the direction of an arrow R (θ direction) in FIG. 8 so that the wafer W is slightly moved along with the wafer plate 15. Accordingly, the positions of the wafer W and the wafer plate 15 with respect to the positioning pins 72 are adjusted to the positions coincident with the electrical characteristic inspection position in the inspection chamber 14.

When slightly moving the wafer W by the sub chuck member 73, the attraction of the wafer plate 15 and the wafer W by the attraction line 13B is released, and after adjusting the positions of the wafer plate 15 and the wafer W, the wafer W and the wafer plate 15 are attracted and held again. At this time, it may be re-checked by the monitoring camera 75 whether the position of the wafer W with respect to the positioning pins 72 is deviated from the target position when the attraction of the wafer W is released. In this way, positioning accuracy of the wafer W with respect to the transfer arm 13A can be achieved.

Now, a process for inspecting the electrical characteristics of the semiconductor devices on a wafer by using the wafer inspection apparatus having the above-described configuration will be explained.

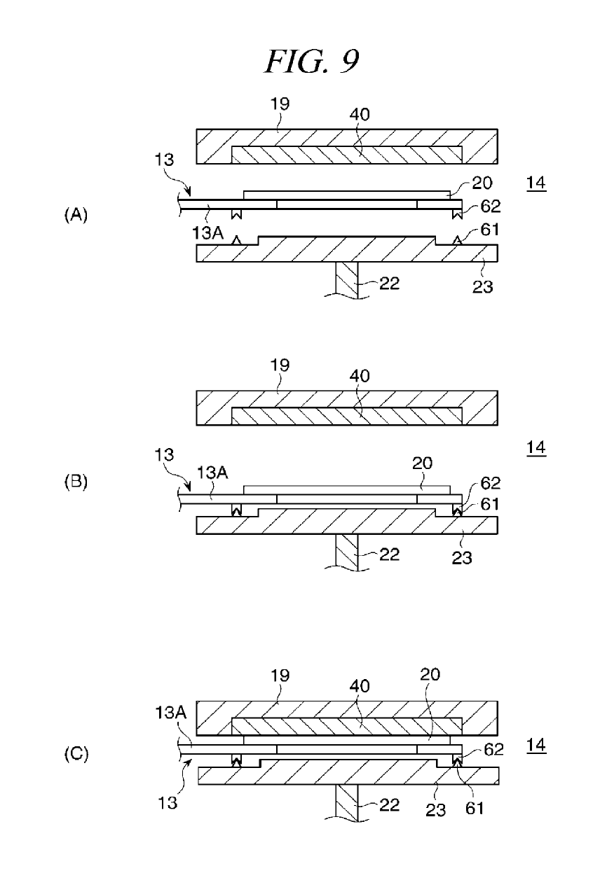

FIGS. 9 to 12 are process diagrams for inspecting the electrical characteristics of the semiconductor devices on a wafer by using the wafer inspection apparatus including the wafer inspection interface of FIG. 3.

First, the probe card 20 is loaded into the inspection chamber 14 by the transfer device 13. That is, the transfer device 13 loads the probe card 20 mounted on the transfer arm 13A into a space between the pogo frame 40 and the chuck member 23 in the inspection chamber 14 (FIG. 9(A)), and locates the transfer arm 13A on the chuck member (FIG. 9(B)). At this time, each of the insertion grooves 62 formed on the bottom surface of the transfer arm 13A and each of the positioning pins 61 formed at the chuck member 23 are fitted to each other, so that the probe card 20 is aligned with the positioning pins 61.

After the positioning of the probe card 20 with respect to the positioning pins 61 is completed, the lifter 22 supporting the chuck member 23 moves up the probe card 20 mounted on the transfer arm 13A along with the chuck member 23. Thus, the probe card 20 is brought into contact with the pogo frame 40 on the bottom surface of the head plate 19, and the probe card 20 is supported by the pogo frame 40 (FIG. 9(C)). At this time, the positional relationship between the inspection chamber 14 and the probe card 20 is checked by a non-illustrated monitoring camera. When the position of the probe card 20 is deviated from the electrical characteristic inspection position of the semiconductor devices, the loading process of the probe card 20 into the inspection chamber 14 is restarted again, and by slightly moving the transfer arm 13A, the position of the probe card is adjusted to the electrical characteristic inspection position in the inspection chamber 14.

At this time, a dummy probe card may be loaded into and held in the inspection chamber 14 previously, and a deviation amount from the electrical characteristic inspection position may be measured in advance. Then, after correcting this deviation amount, the actual probe card 20 may be loaded into the inspection chamber 14.

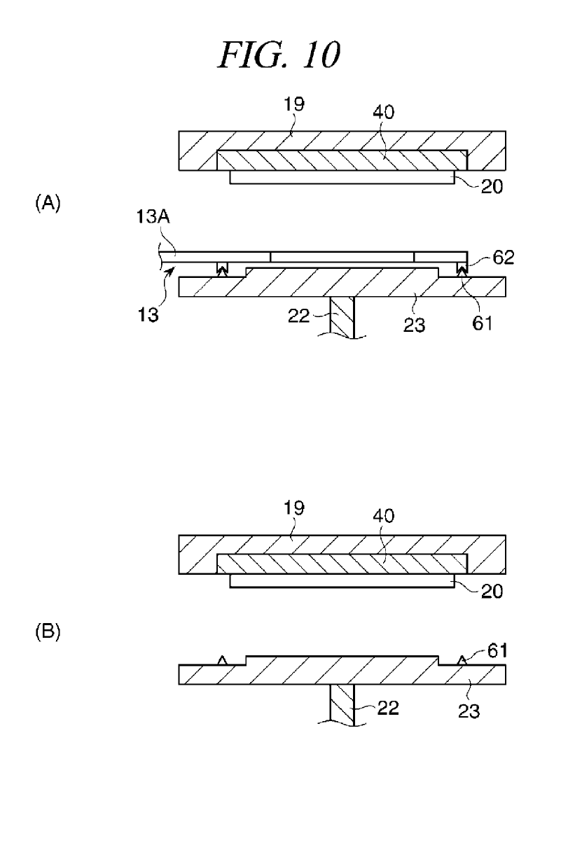

Subsequently, after supporting the probe card 20 by the pogo frame 40, the lifter 22 moves down the transfer arm 13A along with the chuck member 23 (FIG. 10(A)). Thereafter, the transfer arm 13A is retreated out of the inspection chamber 14 (FIG. 10(B)). The position of the probe card 20 supported by the pogo frame 40 in the inspection chamber 14 is detected by the non-illustrated camera and is used when aligning the wafer W with the positioning pins 72, i.e., when aligning the wafer W with the transfer arm 13A in the alignment chamber 12.

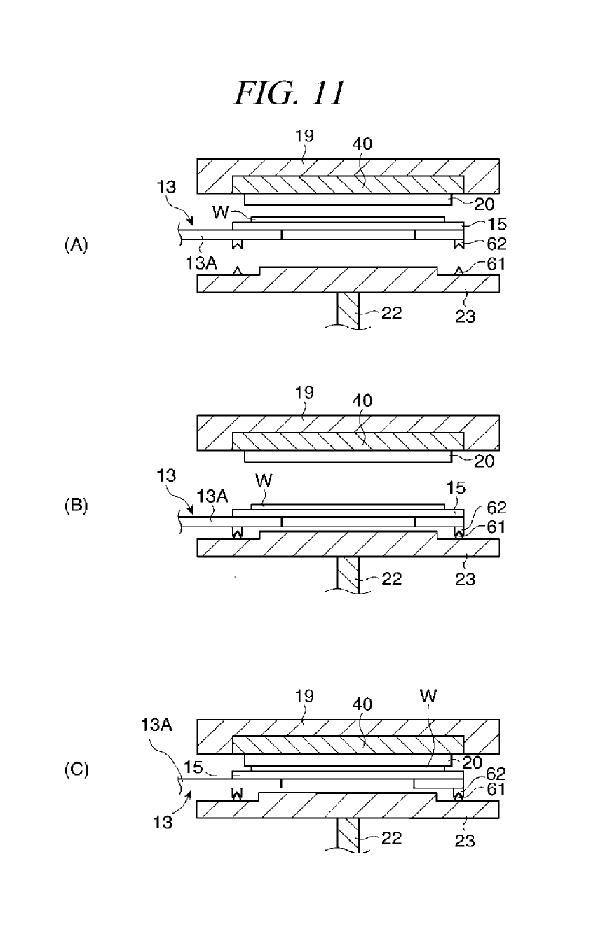

Thereafter, a wafer W is loaded into the inspection chamber 14 into which the probe card 20 has been loaded. That is, the wafer W is mounted on the transfer arm 13A of the transfer device 13 via the wafer plate 15, and the transfer device 13 loads the wafer W (see FIG. 8) aligned with the transfer arm 13A into the inspection chamber 14 and locates the wafer W to face the probe card 20 (FIG. 11(A)). Then, the transfer device 13 places the transfer arm 13A on the chuck member 23 (FIG. 11(B)). At this time, each of the insertion grooves 62 formed on the bottom surface of the transfer arm 13A and each of the positioning pins 61 provided at the chuck member 23 are fitted to each other, so that the transfer arm 13A is aligned with the positioning pins 61, and further, the wafer W is aligned with the positioning pins 61.

After the alignment of the wafer W with the positioning pins 61 is completed, the lifter 22 supporting the chuck member 23 moves up the wafer W mounted on the transfer arm 13A via the wafer plate 15 along with the chuck member 23. Thus, the wafer W is brought into contact with the probe card 20 supported by the pogo frame 40 (FIG. 11(C)). The wafer W is temporarily held to the probe card by a non-illustrated holding device such as a suction device.

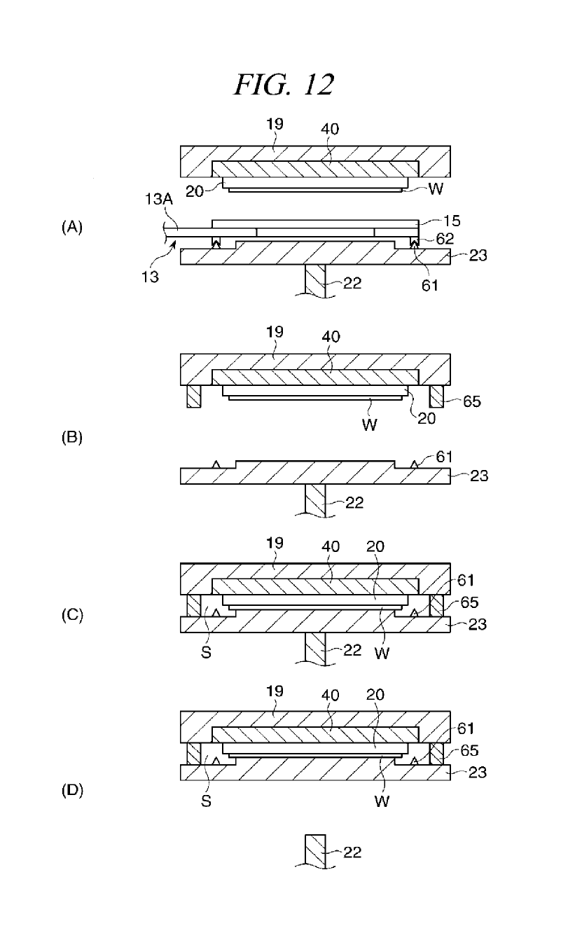

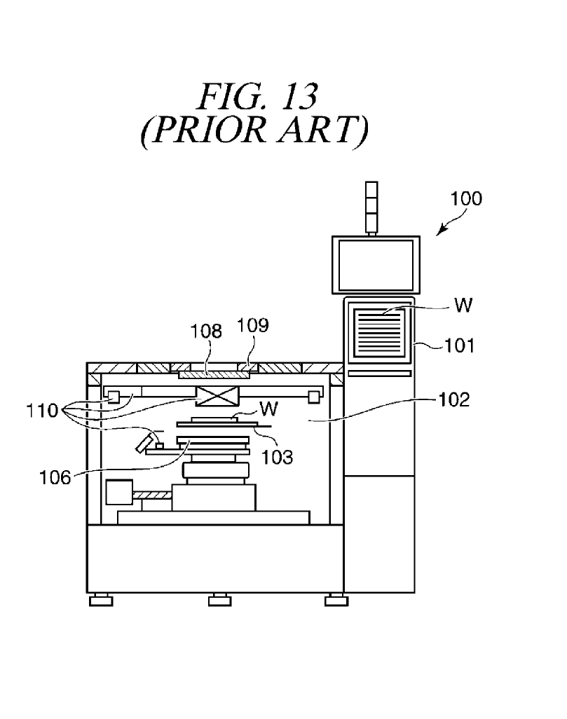

After the wafer W is temporarily held to the probe card 20, the transfer arm 13A on which the wafer plate 15 is mounted is moved down by the lifter 22 along with the chuck member 23 (FIG. 12(A)). Then, the transfer arm 13A mounting the wafer plate 15 thereon is retreated out of the inspection chamber 14 (FIG. 12(B)).

Afterward, the lifter 22 supporting the chuck member 23 moves the chuck member 23 up so that the wafer mounting surface 23C of the chuck member 23 is brought into contact with the wafer W. Here, a seal member 65 is provided between the head plate 19 and the chuck member 23, and there is formed a space S surrounded by the head plate 19, the pogo frame 40, the chuck member 23, and the seal member 65 (FIG. 12(C)). Although the seal member 65 is shown to be located at an outside of the positioning pins 61, the seal member 65 may be positioned at an inside of the positioning pins 61.

Now, the space S is depressurized by a non-illustrated depressurizing device to, e.g., from about −1 kPa to about −50 kPa. Accordingly, the probes 25 provided on the probe card 20 are made to come into firm contact with the electrodes of the semiconductor devices formed on the wafer W. At this time, since the wafer W is aligned with the positioning pins 61, the wafer W is brought into contact with the probe card 20 that has been previously aligned with the positioning pins 61. Thus, a preset positional relationship is achieved, i.e., the wafer W is located at the electrical characteristic inspection position where the electrical characteristics of the semiconductor devices are inspected. Thereafter, the lifter 22 is moved down in the drawing and separated from the chuck member 23 (FIG. 12(D)).

Subsequently, an electric current of a preset value flows to the electrodes of the semiconductor devices from the probes 25 of the probe card 20, and electrical characteristics of the semiconductor devices are inspected. Then, the inspection process is finished.

In accordance with the present illustrative embodiment, the probe card 20 is loaded into the inspection chamber 14 by the transfer arm 13A having the insertion grooves 62 to be fitted to the positioning pins 61 and 72. Then, after aligning the probe card 20 with the positioning pins 61 by fitting the insertion grooves 62 of the transfer arm 13A to the positioning pins 61 on the chuck member 23, the probe card 20 is moved up until it comes into contact with the pogo frame 40 and supported by this pogo frame 40. Subsequently, the wafer W aligned with the transfer arm 13A is also transferred by the same transfer arm 13A into the inspection chamber 14. Then, after aligning the wafer W with the positioning pins 61 by fitting the insertion grooves 62 on the transfer arm 13A to the positioning pins 61 on the chuck member 23, the wafer W is moved up to the surface of the probe card 20 facing the wafer W such that the wafer W comes into contact with the probe card 20. Accordingly, the position of the wafer W with respect to the probe card 20 can be accurately adjusted through the positioning pins 61 provided on the chuck member 23. Thus, the wafer W can be accurately adjusted with respect to the probe care 20 to have the electrical characteristic inspection position where the electrical characteristics of the semiconductor devices are inspected.

Furthermore, in accordance with the present illustrative embodiment, since the opening 13C is formed through the central portion of the transfer arm 13A in the thickness direction thereof, the position of the wafer W with respect to the positioning pins 72 can be slightly adjusted by the sub chuck member 73 configured to pass through the opening 13C in the alignment chamber 12.

In addition, in accordance with the illustrative embodiment, the electrical characteristics of the semiconductor devices on the wafer W are inspected by brining all the probes 25 of the probe card 20 into contact with all the electrodes of the semiconductor devices on the wafer W at one time. Accordingly, productivity of the semiconductor devices can be improved.

In the present illustrative embodiment, the term “electrical characteristic inspection state” for inspecting the electrical characteristics of the semiconductor devices implies a state in which the wafer W is brought into contact with the probe card 20 at an appropriate position, and the probes 25 of the probe card 20 are in contact with the electrodes of the semiconductor devices formed on the wafer W.

While various aspects and embodiments have been described herein, other aspects and embodiments will be apparent to those skilled in the art. The various aspects and embodiments disclosed herein are for the purposes of illustration and are not intended to be limiting. Therefore, the true scope of the disclosure is indicated by the appended claims rather than by the foregoing description, and it shall be understood that all modifications and embodiments conceived from the meaning and scope of the claims and their equivalents are included in the scope of the disclosure.

What is claimed is:

1. A wafer inspection apparatus having an inspection chamber for inspecting electrical characteristics of semiconductor devices formed on a wafer and a transfer device for loading and unloading the wafer into and from the inspection chamber,
wherein the inspection chamber comprises:
a probe card having a multiple number of probes on a surface of the probe card facing the wafer;
a frame that is brought into in contact with a surface of the probe card opposite to the surface of the probe card facing the wafer and supports the probe card;
a table-shaped chuck member disposed to face the probe card with the wafer placed therebetween; and
at least one positioning pin provided on the chuck member, and
wherein the transfer device comprises a transfer arm having at least one recess to be fitted to the at least one positioning pin,
the probe card is loaded into the inspection chamber by the transfer arm, and after the probe card is aligned with the at least one positioning pin by fitting the at least one recess to the at least one positioning pin, the probe card is brought into contact with and supported by the frame, and
the wafer is loaded into the inspection chamber by the transfer arm, and after the wafer is aligned with the at least one positioning pin by fitting the at least one recess to the at least one positioning pin, the wafer is brought into contact with the surface of the probe card facing the wafer to become an electrical characteristic inspection state in which the electrical characteristics of the semiconductor devices are inspected.

2. The wafer inspection apparatus of claim 1,
wherein the transfer device further comprises a wafer plate detachably mounted on the transfer arm, and
the probe card is transferred by being mounted on the transfer arm, and the wafer is transferred by being mounted on the transfer arm via the wafer plate.

3. The wafer inspection apparatus of claim 1,
wherein the transfer arm has an opening formed through a central portion of the transfer arm in a thickness direction thereof.

4. The wafer inspection apparatus of claim 1,
wherein the number of the at least one positioning pin is at least two, and the at least two positioning pins are provided on the chuck member to be arranged along a periphery thereof, and
the number of the at least one recess is at least two, and the at least two recesses are formed on the transfer arm to be fitted to the at least two positioning pins of the chuck member, respectively.

5. The wafer inspection apparatus of claim 1,
wherein at least two positioning recesses are formed on the probe card along a periphery thereof, and
at least two protrusions to be fitted to the at least two positioning recesses of the probe card are provided at the transfer arm.

6. The wafer inspection apparatus of claim 2,
wherein the probe card is attracted to and held on the transfer arm while being transferred, and
the wafer is attracted to and held on the transfer arm via the wafer plate while being transferred.

7. The wafer inspection apparatus of claim 3,
wherein the wafer inspection apparatus further comprises a position adjusting device configured to adjust a position of the wafer with respect to the transfer arm of the transfer device,
the position adjusting device comprises:
a position adjusting chamber;
a base frame that is provided in the position adjusting chamber and has an opening formed through a central portion of the base frame in a thickness direction thereof;
at least one positioning pin provided on a periphery of the base frame; and
a sub chuck member configured to pass through the opening of the base frame,
the sub chuck member is configured to pass through the opening of the base frame and the opening of the transfer arm while the at least one recess of the transfer arm on which the wafer is mounted is fitted to the at least one positioning pin of the base frame, and
the sub chuck member is configured to slightly move the wafer to align the wafer with the transfer arm.

8. The wafer inspection apparatus of claim 7,
wherein the wafer is mounted on the transfer arm via a wafer plate detachably mounted on the transfer arm, and
the sub chuck member is configured to slightly move the wafer along with the wafer plate to align the wafer with the transfer arm.

9. The wafer inspection apparatus of claim 7,
wherein the number of the at least one positioning pin is at least two, and the at least two positioning pins are provided on the base frame to be arranged along the periphery thereof.

10. The wafer inspection apparatus of claim 7,
wherein a position of the at least one positioning pin of the base frame corresponds to a position of the at least one positioning pin of the chuck member.
